(19) United States
(12) Patent Application Publication
(10) Pub. No.: US 2025/0305776 A1
(43) Pub. Date: Oct. 2, 2025

(54) JOINED PIN FINS HEAT SINK

(71) Applicants: DENSO International America, Inc., Southfield, MI (US); Denso Corporation, Kariya City (JP)

(72) Inventor: Siddharth DASGUPTA, Windsor (CA)

(21) Appl. No.: 18/619,022

(22) Filed: Mar. 27, 2024

(51) Int. Cl. F28F 3/02; B33Y 80/00; F28F 3/04

(52) U.S. Cl. CPC F28F 3/022; F28F 3/04; B33Y 80/00; F28F 2215/02

(57) ABSTRACT

A heat sink including a substrate and a plurality of joined pin fins extending outwardly from the substrate and arranged in rows along a longitudinal direction, wherein each row of the plurality of joined pin fins is spaced apart from other rows of the plurality of joined pin fins to define channels for fluid to flow through. An end of each of the joined pin fins is coupled to an end of another of the joined pin fins in a common one of the rows for preventing the fluid from flowing between the plurality of joined pin fins of the common row.

### TECHNICAL FIELD

The present disclosure relates to pin fins for a heat sink for improving heat transfer efficiency and reducing pressure drop. In embodiments, the present disclosure relates to pin fins that are joined or minimally spaced apart from each other at their respective ends.

### BACKGROUND

The performance, lifespan, and safety of many electrical components are dependent on the temperature at which the electrical components operate and a build-up of heat can negatively affect these elements. The temperature of the electrical component may be affected by heat generated from the electrical component or its surrounding environment. Heat sinks are used to dissipate heat from electrical components or other heat-generating devices and prevent the negative effects from a build-up of heat. Some heat sinks use pin fins that extend outward from a base that is in thermal communication with the electrical component. As fluids (e.g., air, water, or the like) flow along the heat sink through the pin fins, the pin fins transfer the heat from the electrical component to the fluid, cooling the electrical component.

The arrangement and design of the pin fins can be used to improve heat transfer of the heat sink by increasing the surface area of the heat sink and reducing the thermal resistance of the heat sink. Increasing the surface area of the heat sink (e.g., increasing the number and/or shape of the pin fins, or the like) typically improves the conductive and convective heat transfer of the heat sink. However, as the surface area and volume of the pin fins increases the flow of the fluid may be disrupted resulting in a diminished convective heat transfer efficiency and a greater pressure drop. This is in part due to adverse pressure gradients causing flow separation and velocity reversal of the fluid amongst the pin fins.

### SUMMARY

Described herein in an embodiment of a heat sink for improving heat transfer efficiency and reducing pressure drop. The heat sink includes a substrate and a plurality of joined pin fins extending outwardly from the substrate and arranged in rows along a longitudinal direction, wherein each row of the plurality of joined pin fins is spaced apart from other rows of the plurality of joined pin fins to define channels for fluid to flow through. An end of each of the joined pin fins is coupled to an end of another of the joined pin fins in a common one of the rows for preventing the fluid from flowing between the plurality of joined pin fins of the common row.

Another embodiment of the heat sink includes a substrate and a plurality of first pin fins extending outwardly from the substrate and arranged in rows along a longitudinal direction, wherein each row of the plurality of first pin fins is spaced apart from other rows of the plurality of first pin fins to define channels for a fluid to flow through. An end of each of the plurality of first pin fins is less than 0.1 millimeters apart from an end of an adjacent first pin fin in a common row to define a gap between the adjacent first pin fins for reducing flow separation and velocity reversal of the fluid.

Another embodiment of the heat sink includes a substrate including a first side, a second side opposite the first side, and a transition point between the first side and the second side. A plurality of first pin fins extend outwardly from the substrate. A plurality of second pin fins extend outwardly from the substrate. The plurality of first pin fins and the plurality of second pin fins are arranged in rows to define channels for a fluid to flow through. An end of each of the plurality of first pin fins is coupled to an end of an adjacent first pin fin within a common row for preventing the fluid from flowing between the ends of plurality of first pin fins. An end of each of the plurality of second pin fins is less than 0.1 mm apart from an end of an adjacent second pin fin within a common row for reducing flow separation and velocity reversal of the fluid. The plurality of first pin fins and the plurality of second pin fins are disposed between the first side and the transition point. The heat sink includes a plurality of third pin fins, wherein an end of each of the plurality third pin fins is spaced apart from an end of an adjacent third pin fin in a common row by more than 0.1 millimeters. The plurality of third pin fins extend along the substrate from adjacent the transition point to the second side.

### BRIEF DESCRIPTION OF THE DRAWINGS

FIG. 1A is a top view of a traditional heat sink according to the prior art;

FIG. 1B is a top zoomed in view of the arrangement of the pin fins of the traditional heat sink shown in FIG. 1A;

FIG. 2A is a top view of a heat sink having a plurality of joined pin fins having a circular shape according an embodiment of the present disclosure;

FIG. 2B is top view of the plurality of joined pin fins shown in FIG. 2A;

FIG. 3A is a top view of the heat sink having a plurality of joined pin fins having an elliptical shape according an embodiment of the present disclosure;

FIG. 3B is top view of the plurality of joined pin fins shown in FIG. 2A adjacent to pin fins that are not joined;

FIG. 4A a top view of the heat sink having a plurality of non-joined pin fins having an elliptical shape wherein ends of the plurality of non-joined pin fins are in close proximity to each other according an embodiment of the present disclosure;

FIG. 4B is top view of the plurality of non-joined pin fins shown in FIG. 4A adjacent to pin fins with ends that are relatively not in close proximity to each other;

FIG. 5A is a perspective side view of two of the plurality of joined pin fins shown in FIG. 3A;

FIG. 5B is a cross-sectional side view of the two of the plurality of joined pin fins shown in FIG. 5A;

FIG. 6A is a side view of the plurality of joined pin fins having a tapered profile that defines a void according to an embodiment of the present disclosure;

FIG. 6B is a side view of the plurality of joined pin fins having a profile that defines multiple voids according to an embodiment of the present disclosure;

FIG. 7 is a side view of the heat sink having the plurality of joined pin fins of FIGS. 5A and 5B arranged in a row according to an embodiment of the present disclosure; and

FIG. 8 is a top view of the heat sink having an arrangement of the plurality of joined pin fins, the plurality of non-joined pin fins with ends in close proximity to each other, and pin fins with ends that are relatively not in close proximity to each other.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative bases for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical application. Various combinations and modifications of the features consistent with the teachings of this disclosure, however, could be desired for particular applications or implementations.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions.

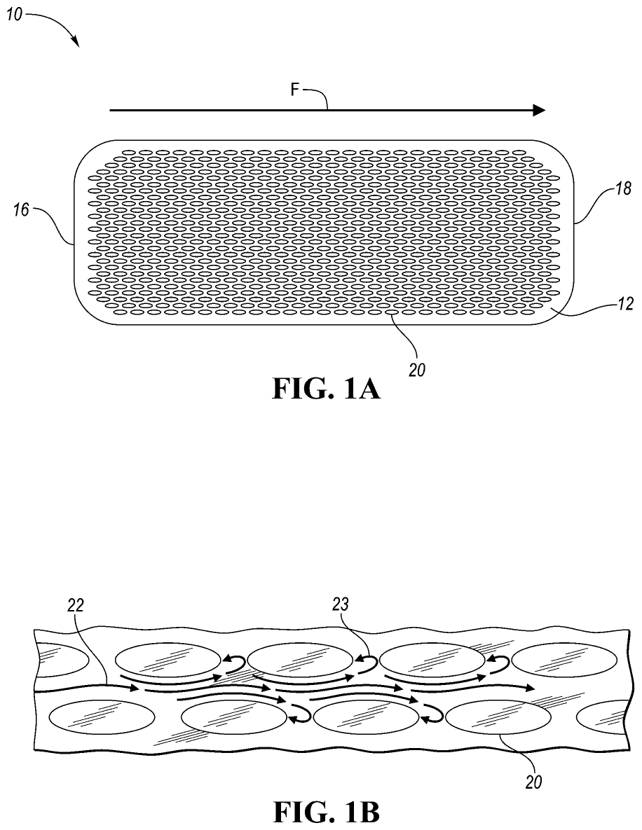

As shown in FIGS. 1A and 1B, according to the prior art, a heat sink 10 for dissipating heat from a device capable of generating heat (e.g., an electrical or computer component, an inverter card, or the like) includes a substrate 12 surrounded by an outer plate. The heat sink 10 may be attached to the device via the outer plate, a thermal paste, a connecting component between the heat sink 10 and the device, or the like. The heat sink 10 may also be connected to a housing (e.g., via the outer plate) that encloses the heat sink 10 for containing and exposing the substrate 12 to a fluid, such as water, air, refrigerant, oil, dielectric fluid, or some other non-conductive thermal transfer fluid, or the like. The fluid is conveyed (by forced or natural convection) through the heat sink 10 from a first side 16 to a second side 18 opposite the first side 16, as indicated by the fluid flow F.

Pin fins 20 extend outwardly from the substrate 12 and along the substrate 12 from the first side 16 to the second side 18 in a staggered arrangement. The pin fins 20 have an elliptical shape and as the fluid flows through the heat sink 10 the flow separates due an adverse pressure gradient and the fluid recirculates in a space between the pin fins 20 with a fluid velocity opposite to the flow direction, as indicated by the velocity vectors 22, 23. The recirculation and potential velocity stagnation results in diminished heat transfer efficiency and a greater pressure drop.

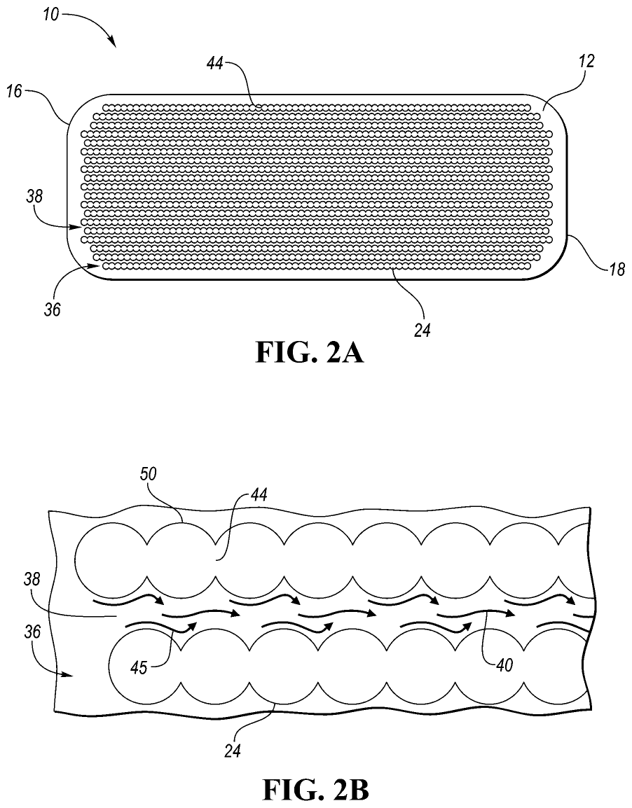

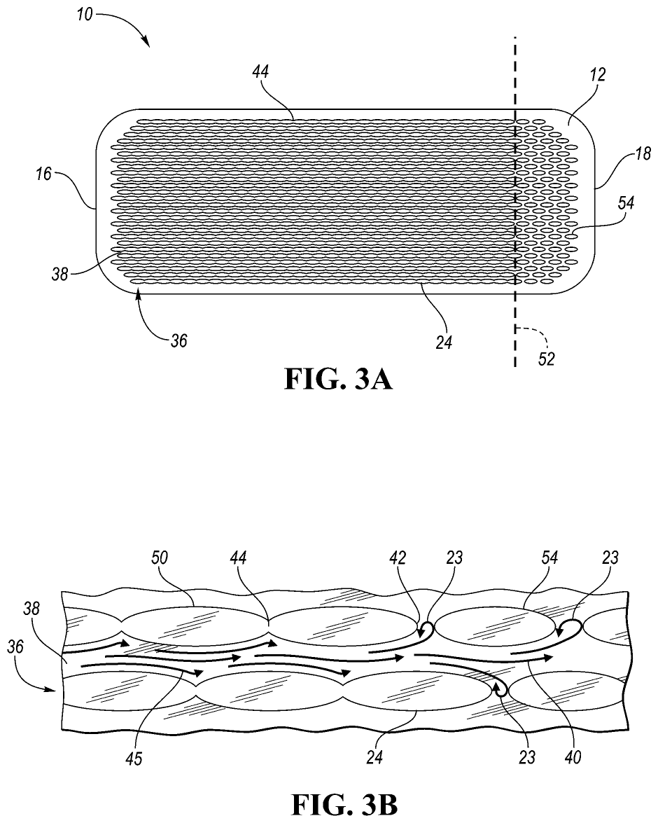

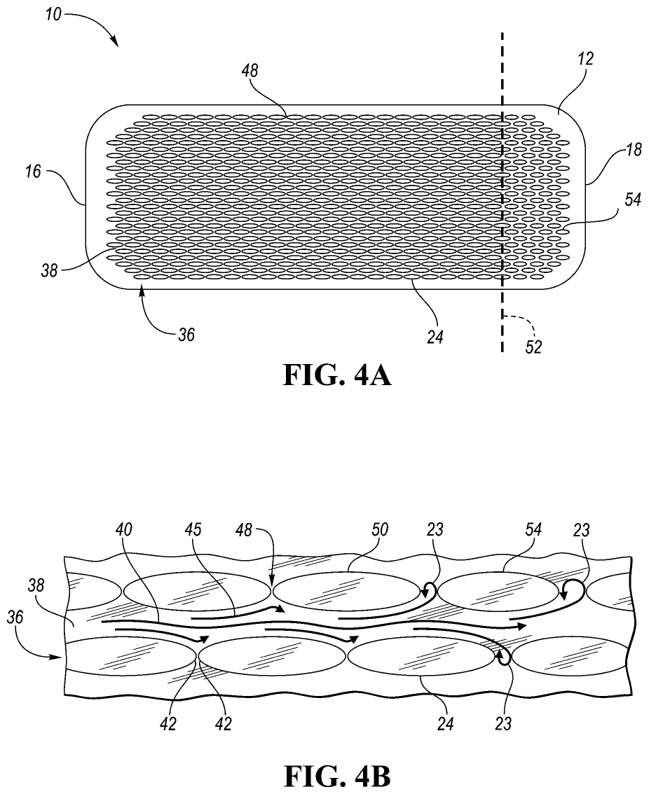

Referring to FIGS. 2A-4B, an embodiment of the heat sink 10 includes a plurality of pin fins 24. As shown in FIGS. 2A and 2B, the plurality of pin fins 24 have a circular shape. As shown in FIGS. 3A-4B, the plurality of pin fins 24 have an elliptical shape. The plurality of pin fins 24 may have other shapes such as airfoil, tear-drop shape, circular, conical, rectangular, or other known shapes, or the like, or a combination or sub-combination thereof. The plurality of pin fins 24 include a longitudinal dimension 26 (i.e., length), a transverse dimension 28 (i.e., width), and a vertical dimension 30 (i.e., a height defined by the distance between a base 32 and a tip 34 of the plurality of pin fins 24). The vertical dimension 30 of the plurality of pin fins 24 may vary amongst the plurality of pin fins 24.

Referring to FIGS. 2A-3B, an embodiment of the heat sink 10 includes a substrate 12 and a plurality of pin fins 24 extending outwardly from the substrate 12 and arranged in rows 36 along a longitudinal direction. Each row 36 of the plurality of pin fins 24 is spaced apart from other rows 36 of the plurality of pin fins 24 to define channels 38 for the fluid to flow through, as indicated by velocity vector 40. An end 42 of each of the plurality of pin fins 24 is coupled to an end 42 of a longitudinally adjacent pin fin 24 in a corresponding or common row 36 for preventing the fluid from flowing between the plurality of pin fins 24 of the corresponding row 36 (as shown by a joined or coupled ends 44). By coupling the ends 42 of the plurality of pin fins 24 the fluid cannot recirculate in a space between the plurality of pin fins 24. Rather, any fluid velocity reversal and/or flow separation (as shown by velocity vector 45) at the joined end 44 is less than or has a lesser magnitude than that of the prior art. Consequently, the heat transfer efficiency is improved and the pressure drop is reduced. For example, when compared to the prior art, CFD simulations indicate that when the plurality of pin fins 24 were joined at their respective ends 42 the overall heat transfer coefficient increased by 3.8 percent and the pressure drop decreased by 6.1 percent (the plurality of pin fins 24 had an elliptical shape similar to FIGS. 1A and 1B).

The coupling of the ends 42 of the plurality of pin fins 24 also increases the cross-sectional area of the plurality of pin fins 24 and causes a reduction in the thermal resistance for conduction. Because conduction through the heat sink 10 can be a bottleneck for improvement to thermal perforce, a reduction in the thermal resistance for conduction leads to a decrease in the total thermal resistance of the heat sink 10. For example, CFD simulations measuring three equidistant sections (sequentially sections 1-3) between an inlet and an outlet of a heat sink 10 showed a reduction in the total thermal resistance of the pin fins portion of the heat sink 10 by 2.9 percent at section 1, 2.4 percent at section 2, and 0.21 percent at section 3 (these results were based on the thermal conductivity of aluminum and assuming a thermal conductivity of about 200 W/mk. Results using copper with an assumed thermal conductivity of 350 W/mk would be even greater). Therefore, a heat sink 10, according to the present embodiment, leads to improvements in heat transfer and pressure drop across the heat sink 10 as compared to the prior art.

The ends 42 of the plurality of pin fins 24 may be coupled or joined by overlapping or merging the shapes of the plurality of pin fins 24. In other words, a portion or segment of the ends 42 of the plurality of pin fins 24 is merged into the shape of the longitudinally adjacent pin fins 24 such that the plurality of pin fins 24 still have an individual and distinct shape. The portion of the ends 42 of the plurality of pin fins 24 that is merged into the shape of the longitudinally adjacent pin fins 24 may be dependent upon the shape of the plurality of pin fins 24, the desired flow properties of the fluid, the manufacturing of the plurality of pin fins 24, or the like, or a combination or sub-combination thereof. For example, the portion of the ends 42 of the plurality of pin fins 24 that is merged into the shape of the longitudinally adjacent pin fins 24 may be a percentage of the cross-sectional area of the of the plurality of pin fins 24 as defined by the longitudinal dimension 26 and the transverse dimension 28 of the plurality of pin fins 24. The percentage of the cross-sectional area of the plurality of pin fins 24 that is merged may be less than 5 percent, 10 percent, 20 percent, or the like, or a sub-combination of ranges thereof. In an embodiment, the plurality of pin fins 24 include an elliptical shape, wherein the ends 42 of the plurality of pin fins 24 define the longitudinal dimension 26.

Referring to FIGS. 4A and 4B, an embodiment of the heat sink 10 includes the plurality of pin fins 24 wherein at least one end 42 of the plurality of pin fins 24 is less than 0.1 mm apart from the end 42 of the longitudinally adjacent pin fin 24 in a corresponding row 36 (as shown by a gap 48) for reducing flow separation and velocity reversal of the fluid. As previously described, the close proximity of the ends 42 of longitudinally adjacent pin fins 24 decreases the degree of fluid velocity reversal and flow separation, improving heat transfer efficiency and decreasing pressure drop. For example, CFD simulations indicate that when the ends 42 of the plurality of pin fins 24 were spaced apart by 0.07 mm the overall heat transfer coefficient increased by 6.7 percent and the pressure drop decreased by 4.1 percent. In some embodiments, the gap 48 may be greater than or equal to 0.07 mm and less than 0.1 mm, greater than 0.01 mm and less than or equal to 0.07 mm, greater than or equal to 0.1 mm and less than 0.2 mm, or the like, or a combination or sub-combination of ranges thereof.

In some embodiments, the gap 48 refers to a void between the ends 42 of longitudinally adjacent pin fins 24. The gap 48 may be measured at any point along the ends 42 of the longitudinally adjacent pin fins 24. For example, the gap 48 may be measured as the distance between the bases 32, tips 34, or some position between the bases 32 and the tips 34 of the longitudinally adjacent pin fins 24. Accordingly, the at least one end of 32 of the plurality of pin fins 24 being less than 0.1 mm apart from the end 42 of the longitudinally adjacent pin fin 24 may refer to the two respective ends 42 being 0.1 mm at the base 32 of the plurality of pin fins 24, or the like.

In some embodiments, the heat sink 10 includes a plurality of pin fins 24 wherein at least two of the plurality of pin fins 24 have a joined end 44 and wherein an end 42 of at least one of the plurality of pin fins 24 is less than 0.1 mm apart from an end 42 of an longitudinally adjacent pin fin 24. In other words, the heat sink 10 includes a plurality of pin fins 24 wherein at least one of the plurality of pin fins 24 is coupled to an end 42 of a longitudinally adjacent pin fin 24 for preventing the fluid from flowing between the joined ends 44 and an end 42 of the at least one of the plurality of pin fins 24 is less than 0.1 mm apart from an end 42 of a longitudinally adjacent pin fin 24 for reducing flow separation and velocity reversal of the fluid. The at least two of the plurality of pin fins 24 having the joined ends 44 and the end 42 of at least one of the plurality of pin fins 24 being less than 0.1 mm apart from the end 42 of an longitudinally adjacent pin fin 24 may be included in the same or different rows 36 of the plurality of pin fins 24. For example, the row 36 of the plurality of pin fins 24 having joined ends 44 may be between or adjacent to the row 36 of the plurality of pin fins 24 having each end 42 of the plurality of pin fins 24 being less than 0.1 mm apart from the end 42 of an longitudinally adjacent pin fin 24 in the common row, or vice versa. Similarly, the row 36 of the plurality of pin fins 24 having the joined ends 44 may be sequentially aligned with the row 36 of the plurality of pin fins 24 having each end 42 of the plurality of pin fins 24 being less than 0.1 mm apart from the end 42 of an longitudinally adjacent pin fin 24 in the common row, such that when the row 36 of the plurality of pin fins 24 having joined ends 44 terminates, the row 36 of the plurality of pin fins 24 having each end 42 of the plurality of pin fins 24 being less than 0.1 mm apart from the end 42 of an longitudinally adjacent pin fin 24 begins and continues in a longitudinal direction that is in alignment with the row 36 of the plurality of pin fins 24 having joined ends 44.

In some embodiments, the rows 36 of the plurality of pin fins 24 may be staggered such that a geometric center 50 of at least one of the plurality of pin fins of one 24 row 36 is adjacent the joined ends 44 or gap 48 of the plurality of pin fins 24 of an adjacent row 36 of the plurality of pin fins 24 in the transverse direction. In other words, the rows 36 of the plurality of pin fins 24 may be offset so as to define the channels 38 based on the shape or profile of the plurality of pin fins 24, and the spacing of the rows 36 of the plurality of pin fins 24. For example, in embodiments where the plurality of pin fins 24 have a circular or elliptical shape the channels 38 may be wave-like or sinusoidal and result in a flow that increases the convection heat transfer coefficient without a significant increase in pressure drop due to the decrease in fluid velocity reversal (e.g., the fluid flow in the channels 38 may be turbulent and enhance heat and momentum transfer between the fluid particles, but no intense mixing occurs between the ends 42 of the plurality of pin fins 24 as a result of vortices caused by fluid velocity reversal). Staggering the rows 36 of the plurality of pin fins 24 also prevents the channels 38 from having sudden expansions of volume that would disrupt the fluid flow (e.g., the channels 38 would expand on both sides if the joined ends 44 of transversely adjacent rows were opposite each other). The rows 36 of the plurality of pin fins 24 may be uniformly or non-uniformly spaced apart from each other such that the channels 38 may have a uniform or non-uniform width or cross-section with respect to each other (e.g., some of the rows 36 of the plurality of pin fins 24 may be closer or farther away from each other). The rows 36 of the plurality of pin fins 24 may extend along the substrate 12 from adjacent the first side 16 to adjacent the second side 18, or from adjacent the first side 16 to adjacent some point between the first side 16 and the second side 18.

In certain embodiments, the rows 36 of the plurality of pin fins 24 may extend along the substrate 12 from adjacent the first side 16 to adjacent a first transition point 52 between the first side 16 and the second side 18. The heat sink 10 includes a plurality of second pin fins 54 extending outwardly from the substrate 12 and extending along the substrate 12 from adjacent the first transition point 52 to adjacent the second side 18. In other words, the plurality of second pin fins 54 may be provided only on one side of the first transition point. Here, the plurality of second pin fins 54 may be slightly spaced apart, and may be in a staggered arrangement or arranged in rows and may further be aligned with the rows 36 of the plurality of pin fins 24 or the channels 38 for influencing the fluid flow properties as fluid exits the channels 38. For example, as shown in FIGS. 3B and 4B, as the fluid exits the channels 38 the fluid may separate and experience velocity reversal 23 in the space between the plurality of pin fins 24 and the plurality of second pin fins 54. This intense mixing may be desirable to create a turbulent fluid flow and increase the heat transfer coefficient for a relatively short distance across the heat sink 10 without significantly increasing the pressure drop. The first transition point 52 may be defined as a percentage of the distance from the first side 16 and the second side 18. For example, the first transition point 52 may be disposed between 90 to 75 percent, 75 to 50 percent, 50 to 25 percent, or the like, or a sub-combination of ranges thereof, of the distance from the first side 16 and the second side 18. The plurality of second pin fins 54 may have a similar or different shape and size to the plurality of pin fins 24. The plurality of second pin fins 54 may also have a uniform or non-uniform shape and size.

In certain embodiments, the rows 36 of the plurality of pin fins 24 including joined ends 44 may extend along the substrate 12 from adjacent the first side 16 to adjacent a second transition point between the first side 16 and the first transition point 52. The rows 36 of the plurality of pin fins 24 including the end 42 of at least one of the plurality of pin fins 24 being less than 0.1 mm apart from the end 42 of the longitudinally adjacent pin fin 24 may extend along the substrate 12 from adjacent the second transition point to the first transition point 52.

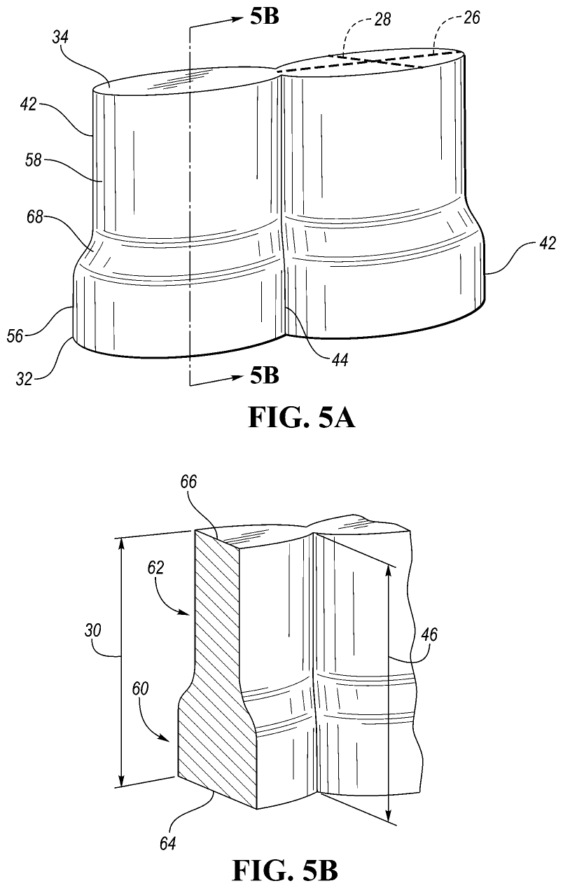

Referring to FIGS. 5A and 5B, in an embodiment, the plurality of pin fins 24 may have a non-uniform cross-section, wherein the vertical dimension 30 of the plurality of pin fins 24 is defined by a first portion 56 and a second portion 58. The first portion 56 is defined by the base 32 being coupled to the substrate 12 and the second portion 58 is defined by the first portion 56 and the tip 34. The first portion 56 has a first cross-sectional shape 60 and the second portion 58 has a second cross-sectional shape 62 that is different from the first cross-sectional shape 60. The first portion 56 may have a first width 64 and the second portion 58 may have a second width 66 wherein the first width 64 is greater than the second width 66. The plurality of pin fins 24 may also include a transition portion 68 between the first portion 56 and the second portion 58 for gradually changing between the first and second cross-sectional shapes 60, 62 of the first and second portions 56, 58. It is also contemplated that the plurality of pin fins may include more than two different cross-sectional shapes, such as three, four, or more than four. In addition, in some embodiments, the first cross-sectional shape 60 and/or the second cross-sectional shape 62 of at least one of the plurality of joined pin fins 24 may be different from the first cross-sectional shape 60 and/or the second cross-sectional shape 62 of another of the plurality of joined pin fins 24.

Referring to FIGS. 2A-3B, and 5A-7, in some embodiments, the joined ends 44 of the plurality of pin fins 24 may include a joined height 46 wherein the joined height 46 is less than the vertical dimension 30 of the plurality of pin fins 24. In other words, the ends 42 of the adjacent plurality of pin fins 24 in corresponding rows 36 are coupled together from the base 32 to the joined height 46 to define a void 47 from the joined height 46 to the tip 34 of the plurality of pin fins 24. The fluid may flow through the void 47 but not between the joined ends 44 of the plurality of pin fins 24. Coupling the ends 42 of the plurality of pin fins 24 from the base 32 to the joined height 46 allows for reduction in the thermal resistance for conduction. The joined height 46 may be defined as a percentage of the vertical dimension 30 (e.g., the joined height 46 may be between 25 to 50 percent, 50 to 75 percent, 75 to 100 percent, or the like or a sub-combination of ranges thereof, of the vertical dimension 30). In some embodiments, the void 47 may be disposed between the base 32 and the tip 34 so as to create a pore through which the fluid may flow through the joined ends 44. In other words, the joined ends 44 of the plurality of pin fins 24 are spaced apart from the base 32 to the tip 34, spaced apart from and between the base 32 and the tip 34, or the like.

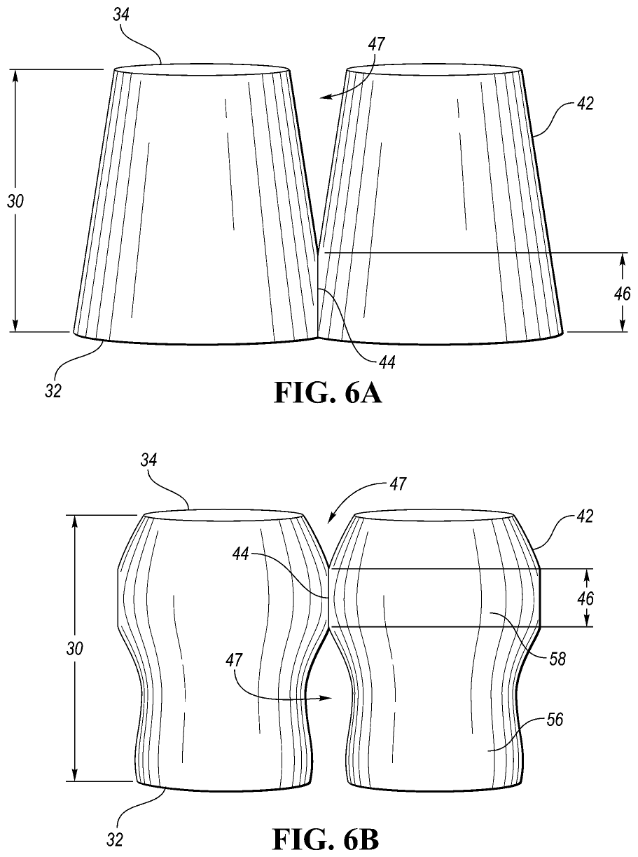

The shape of the plurality of pin fins 24 may define the joined ends 44 and the void 47. As shown in FIG. 6A, the ends 42 of the plurality of pin fins 24 are tapered from the tip 34 to the base 32, progressively decreasing the length of the plurality of pin fins 24 along the longitudinal dimension 26 (e.g., a trapezoidal profile, or the like). The plurality of pin fins 24 are coupled at the joined end 44 where the longitudinal dimensions 26 and ends 42 of the plurality of pin fins 24 merge. The void 47 progressively increases along the longitudinal dimension 26 from the joined end 44 to the tip 34. In certain embodiments, the base 32 and tip 34 may be off center with respect to each other such that the end 42 of the plurality of pin fins 24 are angled (e.g., the plurality of pin fins 24 may have a rhomboid, or parallelogram profile, or the like).

In some embodiments, there may be a plurality of voids 47. For example, as shown in FIG. 6B, the plurality of pin fins 24 may have second portion 58 with a bulbous shape that is connected to the substrate 12 by the first portion 56, in which the first portion 56 has a smaller or narrower longitudinal dimension 26 than the second portion 58 (e.g., the plurality of pin fins 24 have a mushroom-like profile where the first portion 56 resembles a stalk and the second portion 58 resembles a head of a mushroom, or the like). A first void 47 is disposed between the bases 32 and the joined end 44, and a second void 47 is disposed between the joined end 44 and the tips 34.

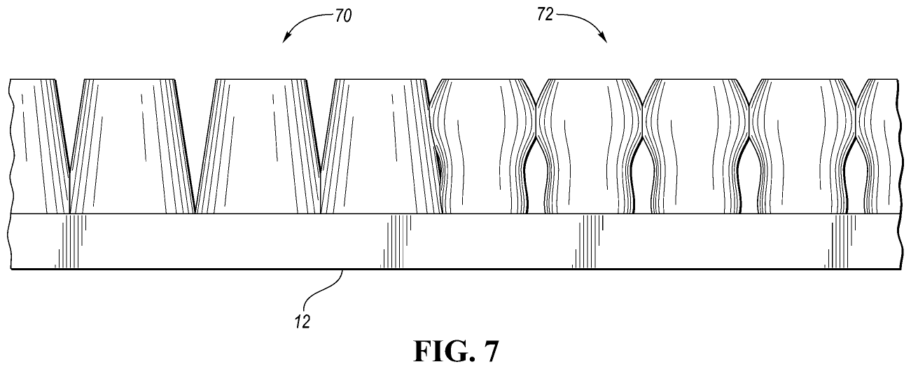

Referring to FIG. 7, in an embodiment, the plurality of pin fins 24 includes a first set of pin fins 70 as shown in FIG. 6A and a second set of pin fins 72 as shown in FIG. 6B. The first set and the second set of pin fins 70, 72 may be arranged in a common row 36 such that the row 36 of the plurality of pin fins 24 transitions from the first set of pin fins 70 to the second set of pin fins 72, or vice versa. There may be several transitions from the first set of pin fins 70 to the second set of pin 72 (and vice versa) in a common row 36. In some embodiments, rows 36 are staggered such that the first set of pin fins 70 in a row 36 is adjacent to the second set of pin fins 72 in an adjacent row 36.

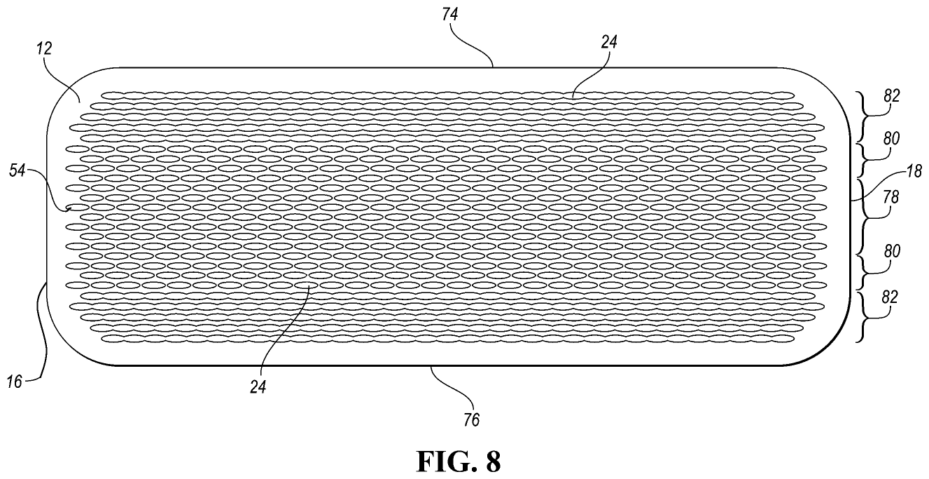

Referring to FIG. 8, in an embodiment, the heat sink 10 includes rows 36 of the plurality of pin fins 24 and the plurality of second pin fins 54, wherein the plurality of pin fins 24 include joined ends 44 and ends 42 being less than 0.1 mm apart from an end 42 of a longitudinally adjacent pin fin 24 in a common row 36. In other words, the heat sink 10 includes a row 36 of the plurality of pin fins 24 having joined ends 44, a row 36 of the plurality of pin fins 24 having ends 42 less than 0.1 mm apart from an end 42 of a longitudinally adjacent pin fin 24 in the row 36, and a row 36 of the plurality of second pin fins 54. The rows 36 of the plurality of pin fins 24 and the plurality of second pin fins 54 extend along the substrate 12 from adjacent the first side 16 to adjacent the second side 18.

The rows 36 of the plurality of pin fins 24 and the plurality of second pin fins 54 may be arranged according to a desired fluid flow, pressure drop, heat transfer, or the like. For example, the substrate includes a third side 74 and a fourth side 76 opposite the third side 74, wherein the third side 74 and the fourth side 76 connect the first side 16 to the second side 18. The heat sink 10 may include rows 78 of the plurality of second pin fins 54 disposed centrally on the substrate 12 between the third side 74 and the fourth side 76 of the substrate 12. The rows 78 of the of the plurality of second pin fins 54 are sandwiched between rows 80 of the plurality of pin fins 24 having ends 42 less than 0.1 mm apart from an end 42 of a longitudinally adjacent pin fin 24 in the common row 36 (i.e., the rows 80 of the plurality of pin fins 24 having ends 42 less than 0.1 mm apart from an end 42 of a longitudinally adjacent pin fin 24 in the common row 36 surround or are on both sides of the rows 78 of the plurality of second pin fins 54). Rows 82 of the plurality of pin fins 24 having joined ends 44 may be disposed transversely adjacent to the rows 80 of the plurality of pin fins 24 having ends 42 less than 0.1 mm apart. In other words, there is one set of rows 78 of the second pin fins 54 located centrally on the substrate 12, two sets of rows 80 of the plurality of pin fins 24 having ends 42 less than 0.1 mm apart from an end 42 of a longitudinally adjacent pin fin 24 in their common row 36, and two sets of rows 82 of plurality of pin fins 24 having joined ends 44. In some embodiments, the heat sink 10 includes rows 80 and 82 of the plurality of pin fins 24. In other embodiments, the heat sink 10 includes rows 78 of the second pin fins 54 and either rows 80 or 82 of the plurality of pin fins 24. Other arrangements, distributions, configurations, are contemplated and considered to be within the subject of this disclosure (e.g., alternating rows 78, 80, and 82 from the third side 74 to the fourth side 76, more or less sets of rows 78, 80, and 82, or the like).

The substrate 12 and plurality of pin fins 24 may composed of any material capable of transferring heat from the device to the fluid (e.g., copper, aluminum, steel, a metal alloy, or the like). The plurality of pin fins 24 may be formed by precision forging, additive manufacturing, die casting, CNC manufacturing, extrusion, or the like. In some embodiments, the plurality of pin fins 24 are formed using additive manufacturing methods, such as with metal powders. In embodiments where the plurality of the pin fins 24 include joined ends 44, the plurality of pin fins 24 are formed such that each of the plurality of pin fins 24 has its own individual and discrete shape. The rows 36 of the plurality of pin fins 24 having joined ends 44 may be formed sequentially or contemporaneously. In particular, using additive manufacturing allows for a precise, controlled, and repeatable method of manufacturing the plurality of pin fins 24 such that the shape, size, and arrangement of the plurality of pin fins 24 and/or rows 36 of the plurality of pin fins 24 are consistent with the desired heat transfer, fluid flow properties, and pressure drop.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A heat sink comprising:
a substrate; and
a plurality of joined pin fins extending outwardly from the substrate and arranged in rows along a longitudinal direction, wherein each row of the plurality of joined pin fins is spaced apart from other rows of the plurality of joined pin fins to define channels for fluid to flow through;
wherein each of the joined pin fins is coupled to another of the joined pin fins in a common row.

2. The heat sink of claim 1 further comprising:
a plurality of non-joined pin fins extending outwardly from the substrate;
wherein a transition point exists between a first side of the substrate and a second side of the substrate;
wherein the plurality of joined pin fins extend along the longitudinal direction from the first side of the substrate to the transition point; and
wherein the plurality of non-joined pin fins extend from the transition point to the second side of the substrate.

3. The heat sink of claim 1 wherein the plurality of joined pin fins include an elliptical or airfoil shape along at least a portion of a height of the plurality of joined pin fins.

4. The heat sink of claim 1 wherein the plurality of joined pin fins are formed by additive manufacturing.

5. The heat sink of claim 1 wherein the rows of the plurality of joined pin fins are staggered such that a center of one of at least one of the plurality of joined pin fins of one row of the plurality of joined pin fins is transversely adjacent the coupled ends of the plurality of joined pin fins of a transversely adjacent row of the plurality of joined pin fins.

6. The heat sink of claim 1 wherein the plurality of joined pin fins include a height defined by a first portion coupled to the substrate and a second portion, wherein the first portion has a first cross-sectional shape and the second portion has a second cross-sectional shape different from the first cross-sectional shape.

7. The heat sink of claim 6 wherein the first cross-sectional shape or the second cross-sectional shape of at least one plurality of joined pin fins is different from the first cross-sectional shape or the second cross-sectional shape of another of the plurality of joined pin fins.

8. The heat sink of claim 1 wherein the plurality of joined pin fins include a base connected to the substrate, a tip distal to the base, a vertical dimension defined by a distance between the based and the tip, and a joined height defined by the coupling of the plurality of pin fins; and
wherein the joined height is less than the vertical dimension.

9. The heat sink of claim 8 wherein the plurality of joined pin fins are coupled at their respective ends to define a joined end, wherein the joined end is spaced apart from and between the base and the tip.

10. A heat sink comprising:
a substrate; and
a plurality of first pin fins extending outwardly from the substrate and arranged in rows along a longitudinal direction, wherein each row of the plurality of first pin fins is spaced apart from other rows of the plurality of first pin fins to define channels for a fluid to flow through;
wherein an end of each of the plurality of first pin fins is less than 0.1 millimeters apart from an end of an adjacent first pin fin in a common row to define a gap between the adjacent first pin fins for reducing flow separation and velocity reversal of the fluid.

11. The heat sink of claim 10 further comprising:
a plurality of second pin fins extending outwardly from the substrate;
wherein a transition point exists between a first side of the substrate and a second side of the substrate;
wherein the plurality of first pin fins extend from the first side of the substrate to the transition point; and
wherein the plurality of second pin fins extend from the transition point to the second side of the substrate.

12. The heat sink of claim 10 wherein the plurality of first pin fins are formed by additive manufacturing.

13. The heat sink of claim 10 wherein the rows of the plurality of first pin fins are staggered such that a center of one of the plurality of first pin fins of one row of the plurality of first pin fins is transversely adjacent the gap of the plurality of first pin fins of transversely adjacent rows of the plurality of first pin fins.

14. The heat sink of claim 10 wherein the plurality of first pin fins include a height defined by a first portion coupled to the substrate and a second portion, wherein the first portion has a first cross-sectional shape and the second portion has a second cross-sectional shape different from the first cross-sectional shape.

15. A heat sink comprising:
a substrate including a first side and a second side opposite the first side;
a plurality of first pin fins;
a plurality of second pin fins;
a plurality of third pin fins;
wherein the plurality of first pin fins, the plurality of second pin fins, and the plurality of third pin fins extend outwardly from the substrate and are arranged in rows to define channels for a fluid to flow through;
wherein an end of each of the plurality of first pin fins is coupled to an end of an adjacent first pin fin within a common row for preventing the fluid from flowing between the ends of plurality of first pin fins;
wherein an end of each of the plurality of second pin fins is less than 0.1 mm apart from an end of an adjacent second pin fin within a common row for reducing flow separation and velocity reversal of the fluid; and
wherein an end of each of the plurality third pin fins is spaced apart from an end of an adjacent third pin fin in a common row by more than 0.1 millimeters.

16. The heat sink of claim 15 further comprising a transition point between the first side and the second side;
wherein the plurality of first pin fins and the plurality of second pin fins are disposed between the first side and the transition point; and
wherein the plurality of third pin fins extend along the substrate from adjacent the transition point to the second side.

17. The heat sink of claim 15 wherein the row of the plurality of first pin fins, the row of the plurality of second pin fins, and the row of the plurality of third pin fins extend along the substrate from adjacent the first side to adjacent the second side.

18. The heat sink of claim 15 wherein the at least one of the rows of the plurality of first pin fins is sequentially aligned within at least one of the rows of the plurality of second pin fins.

19. The heat sink of claim 15 wherein the row of the plurality of first pin fins is disposed transversely adjacent the row of the plurality of second pin fins or the row of the plurality of third pin fins.

20. The heat sink of claim 15 wherein the plurality of first pin fins and the plurality of second pin fins include an elliptical or airfoil shape along at least a portion of a height of the plurality of first pin fins, the plurality of second pin fins, or the plurality of third pin fins.
